(19) United States
(12) Patent Application Publication
(10) Pub. No.: US 2026/0133227 A1
(43) Pub. Date: May 14, 2026

(54) OSCILLOSCOPE

(71) Applicant: RIGOL TECHNOLOGIES CO., LTD., Suzhou (CN)

(72) Inventors: Hui SHI, Suzhou (CN); Yue WANG, Suzhou (CN)

(21) Appl. No.: 19/435,227

(22) Filed: Dec. 29, 2025

Related U.S. Application Data
(63) Continuation of application No. PCT/CN2024/122390, filed on Sep. 29, 2024.

(30) Foreign Application Priority Data
Apr. 22, 2024 (CN) 202410482213.6

(51) Int. Cl. G01R 13/02

(52) U.S. Cl. CPC G01R 13/0254; G01R 13/0236; G01R 13/0272

(57) ABSTRACT

An oscilloscope is provided. The oscilloscope includes a first data processing unit (10) configured to send a first synchronization signal to a first multi-output unit (20); the first multi-output unit (20) configured to output a second synchronization signal to N sampling channels, respectively, according to the first synchronization signal; an analog-to-digital conversion unit (30) configured to perform signal sampling to determine first sampled data, and synchronously transmit the first sampled data to a second data processing unit (40) of a sampling channel to which the analog-to-digital conversion unit (30) belongs, according to the second synchronization signal; and the second data processing unit (40) configured to process the received first sampled data and send second sampled data obtained by processing the first sampled data to the first data processing unit (10).

### CROSS REFERENCE TO RELATED APPLICATIONS

The present application is a continuation application of International Application No. PCT/CN 2024/122390, filed on Sep. 29, 2024, which claims the priority of Chinese patent application No. 2024104822136, filed on Apr. 22, 2024, entitled “Bandwidth Limitation Circuit and Front End Circuit,” the entire contents of which are hereby incorporated by reference.

### TECHNICAL FIELD

The present disclosure relates to the field of signal measurement, and in particular, to an oscilloscope.

### BACKGROUND

A digital oscilloscope generally consists of a front end analog circuit, an analog-to-digital converter (ADC), a data processing unit, and a control processor. The data processing unit is often implemented using a Field-Programmable Gate Array (FPGA).

With the development of the digital oscilloscope, bandwidth and sampling rates are increasingly high, and the number of sampling channels is increasing. The oscilloscope with a high-bandwidth and a high sampling rate also often requires the use of a real-time digital filter to perform real-time data processing, which are all implemented by the FPGA, and thus the demand for FPGA resources (such as a pin resource and a logic resource) within the oscilloscope is increasing. It is becoming increasingly difficult to use one FPGA within the oscilloscope to implement data processing for all ADCs and sampling channels.

### SUMMARY

Embodiments of the present disclosure provide an oscilloscope.

According to a first aspect of the present disclosure, an oscilloscope is provided, where the oscilloscope has N sampling channels and the oscilloscope includes:
a first data processing unit configured to send a first synchronization signal to a first multi-output unit;
the first multi-output unit configured to output a second synchronization signal to the N sampling channels, respectively, according to the first synchronization signal, where N is an integer greater than or equal to 2; and
an analog-to-digital conversion unit and a second data processing unit corresponding to each of the N sampling channels, where the analog-to-digital conversion unit is configured to perform signal sampling to determine first sampled data, and synchronously transmit the first sampled data to the second data processing unit of a sampling channel to which the analog-to-digital conversion unit belongs, according to the second synchronization signal; and the second data processing unit is configured to process the received first sampled data and send second sampled data obtained by processing the first sampled data to the first data processing unit.

In some embodiments, the analog-to-digital conversion unit is specifically configured to synchronize start time of transmitting the first sampled data to the second data processing unit of the sampling channel to which the analog-to-digital conversion unit belongs, according to the second synchronization signal.

In some embodiments, the oscilloscope further includes:
a reference clock unit configured to send a first reference clock signal to the first multi-output unit,
where the first multi-output unit is configured to respectively output a first synchronization clock signal to analog-to-digital conversion units respectively corresponding to the N sampling channels according to the first reference clock signal, and
the analog-to-digital conversion unit is further configured to synchronize a sampling frequency of the signal sampling according to the first synchronization clock signal.

In some embodiments, the first multi-output unit is further configured to synchronize the first synchronization signal with the first reference clock signal.

In some embodiments, the analog-to-digital conversion unit is further configured to output a second synchronization clock signal to the second data processing unit of the sampling channel to which the analog-to-digital conversion unit belongs, according to the first synchronization clock signal; and

the second data processing unit is further configured to synchronize processing of the first sampled data according to the second synchronization clock signal.

In some embodiments, the oscilloscope further includes:
a second multi-output unit configured to respectively output a third synchronization signal to second data processing units respectively corresponding to the N sampling channels and the first data processing unit;
where the third synchronization signal is configured to synchronize a frame clock of a data frame corresponding to the second sampled data transmitted between the second data processing unit and the first data processing unit.

In some embodiments, the first data processing unit is configured to send a fourth synchronization signal to the second multi-output unit; and
the second multi-output unit is specifically configured to output the third synchronization signal according to the fourth synchronization signal.

In some embodiments, the oscilloscope further includes:
a reference clock unit configured to send a second reference clock signal to the second multi-output unit,
where the second multi-output unit is configured to respectively output a third synchronization clock signal to the second data processing units respectively corresponding to the N sampling channels and the first data processing unit according to the second reference clock signal; and
the third synchronization clock signal is configured to synchronize a transmission clock of the data frame corresponding to the second sampled data transmitted between the second data processing unit and the first data processing unit.

In some embodiments, the first data processing unit is further configured to output a fifth synchronization signal to the second data processing units respectively corresponding to the N sampling channels, respectively; and
the second data processing unit is further configured to synchronize start time of transmitting the second sampled data to the first data processing unit according to the fifth synchronization signal.

In some embodiments, the oscilloscope further includes:
a third multi-output unit respectively corresponding to each of the N sampling channels, and configured to receive the second synchronization signal and output a sixth synchronization signal to the analog-to-digital conversion unit of the sampling channel to which the third multi-output unit belongs, according to the second synchronization signal,
where the analog-to-digital conversion unit is configured to synchronously transmit a frame clock of a data frame corresponding to the first sampled data to the second data processing unit of the sampling channel to which the analog-to-digital conversion unit belongs, according to the sixth synchronization signal.

In some embodiments, the oscilloscope further includes:
a reference clock unit configured to transmit a third reference clock signal to the first multi-output unit,
where the first multi-output unit is configured to respectively output a fourth synchronization clock signal to third multi-output units respectively corresponding to the N sampling channels according to the third reference clock signal;
the third multi-output unit is further configured to output a fifth synchronization clock signal to the analog-to-digital conversion unit of the sampling channel to which the third multi-output unit belongs, according to the fourth synchronization clock signal; and
the analog-to-digital conversion unit is configured to synchronously transmit a transmission clock of the data frame corresponding to the first sampled data to the second data processing unit of the sampling channel to which the analog-to-digital conversion unit belongs, according to the fifth synchronization clock signal.

In some embodiments, the first multi-output unit is further configured to output a seventh synchronization signal to the first data processing unit according to the first synchronization signal;
the third multi-output unit is further configured to output an eighth synchronization signal to the second data processing unit of a sampling channel to which the third multi-output unit belongs, according to the second synchronization signal;
the seventh synchronization signal and the eighth synchronization signal are configured to synchronize a frame clock of a data frame corresponding to the second sampled data transmitted between the second data processing unit and the first data processing unit.

In some embodiments, the oscilloscope further includes:
the third multi-output unit further configured to output a sixth synchronization clock signal to the second data processing unit according to the fourth synchronization clock signal;
the first multi-output unit configured to output a seventh synchronization clock signal to the first data processing unit according to the third reference clock signal;
the sixth synchronization clock signal and the seventh synchronization clock signal are configured to synchronize a transmission clock of a data frame corresponding to the second sampled data transmitted between the second data processing unit and the first data processing unit.

In some embodiments, the first data processing unit is further configured to respectively output a ninth synchronization signal to second data processing units respectively corresponding to the N sampling channels; and
the second data processing unit is further configured to synchronize start time of transmitting the second sampled data to the first data processing unit according to the ninth synchronization signal.

In some embodiments, the second data processing unit is further configured to output a tenth synchronization signal to the analog-to-digital conversion unit of the sampling channels to which the second data processing unit belongs, according to the ninth synchronization signal;
the analog-to-digital conversion unit is further configured to synchronize start time of transmitting the first sampled data to the second data processing unit according to the tenth synchronization signal.

According to embodiments of the present disclosure, an oscilloscope includes: a first data processing unit configured to transmit a first synchronization signal to a first multi-output unit; the first multi-output unit configured to respectively output a second synchronization signal to the N sampling channels according to the first synchronization signal, where N is an integer greater than or equal to 2; and an analog-to-digital conversion unit and a second data processing unit corresponding to each of the N sampling channels corresponds to, where the analog-to-digital conversion unit is configured to perform signal sampling to determine first sampled data, and synchronously transmit the first sampled data to the second data processing unit of the sampling channel to which the analog-to-digital conversion unit belongs, according to the second synchronization signal; and the second data processing unit is configured to process the received first sampled data and send second sampled data obtained by processing the first sampled data to the first data processing unit. As such, the oscilloscope converts the first synchronization signal into second synchronization signals respectively output to different sampling channels via the first multi-output unit and is configured to synchronize start time of transmitting the first sampled data performed by the analog-to-digital conversion units, thereby realizing synchronization of start time of transmitting the first sampled data performed by multiple sampling channels, reducing the delay difference in data transmission between the channels of the oscilloscope, and improving the signal detection precision of the oscilloscope.

### BRIEF DESCRIPTION OF DRAWINGS

FIG. 1 is a schematic diagram illustrating a composition structure of an oscilloscope according to an exemplary embodiment;

FIG. 2 is a schematic diagram illustrating another composition structure of an oscilloscope according to an exemplary embodiment;

FIG. 3 is a schematic diagram illustrating yet another composition structure of an oscilloscope according to an exemplary embodiment;

FIG. 4 is a schematic diagram illustrating still another composition structure of an oscilloscope according to an exemplary embodiment;

FIG. 5 is a schematic diagram illustrating still another composition structure of an oscilloscope according to an exemplary embodiment;

FIG. 6 is a schematic diagram illustrating still another composition structure of an oscilloscope according to an exemplary embodiment; and

FIG. 7 is a schematic diagram illustrating still another composition structure of an oscilloscope according to an exemplary embodiment.

### DETAILED DESCRIPTION

To make the technical solutions and beneficial effects of the present disclosure more obvious and understandable, detailed description will be given below by enumerating specific embodiments. The accompanying drawings are not necessarily drawn to scale, and local features may be enlarged or reduced to display the details of local features more clearly. Unless otherwise defined, technical and scientific terms used herein have the same meaning as those commonly understood by those skilled in the art to which the present disclosure belongs.

The embodiments of the present disclosure are not exhaustive, but are merely illustrative of some embodiments and do not specifically limit the protection scope of the present disclosure. In the case of no contradiction, each step in a certain embodiment can be implemented as an independent embodiment, and the steps can be combined arbitrarily. For example, a solution obtained by removing some steps from a certain embodiment can also be implemented as an independent embodiment, and the order of steps in a certain embodiment can be arbitrarily exchanged. In addition, optional implementations in a certain embodiment can be arbitrarily combined. Furthermore, the embodiments can be arbitrarily combined. For example, part or all of the steps in different embodiments can be arbitrarily combined, and a certain embodiment and optional implementations of other embodiments can be arbitrarily combined.

In each embodiment of the present disclosure, unless otherwise specified and there is a logical conflict, the terms and/or descriptions between the embodiments are consistent and can refer to each other. Technical features in different embodiments can be combined to form a new embodiment according to their inherent logical relationships.

The terms used in the embodiments of the present disclosure are only for the purpose of describing specific embodiments and are not intended to limit the embodiments of the present disclosure.

In the embodiments of the present disclosure, unless otherwise stated, an element expressed in the singular form, such as “a,” “an,” “the,” “above-mentioned,” “said,” “aforementioned,” “this,” etc., may mean “one and only one,” or may mean “one or more,” “at least one,” etc. For example, In the case that an article such as “a,” “an,” “the,” etc. are used in the translation, a noun following the article can be understood as a singular expression form or a plural expression form.

In the embodiments of the present disclosure, “a plurality of” refers to two or more.

In some embodiments, terms such as “at least one of,” “one or more,” “a plurality of,” “multiple,” etc., can be exchanged.

In some embodiments, expressions such as “at least one of A and B,” “A and/or B,” “in one case A, in another case B,” “one case A, another case B,” etc., may, according to the situations, include the following technical solutions: in some embodiments, A (executing A independently of B), in some embodiments, B (executing B independently of A); in some embodiments, selectively executing A or B (A and B are selectively executed); in some embodiments, A and B (both A and B are executed). The same also applies when there are more branches such as A, B, C, etc.

In some embodiments, expressions such as “A or B,” etc., may, according to the situations, include the following technical solutions: in some embodiments, A (performing A independently of B); in some embodiments, B (performing B independently of A); in some embodiments, selectively executing A or B (A and B are selectively executed). The same also applies when there are more branches such as A, B, C, etc.

Prefixes such as “first” and “second,” etc., used in the embodiments of the present disclosure are merely used to distinguish different descriptive objects, and are not intended to limit locations, order, priority, values, or contents of the descriptive objects. The description of the descriptive objects refers to claims or the context of the embodiments and should not be construed as undue limitation due to the use of the prefixes. For example, if the descriptive object is a “field,” ordinal numbers preceding “field” in “first field” and “second field” do not limit a location or an order between fields. “First” and “second” do not limit whether the fields modified by the “first” and “second” are in a same message, nor do they limit the order of the “first field” and the “second field”. For another example, if the descriptive object is a “tier/grade/class,” ordinal numbers preceding “tier/grade/class” in “first tier/grade/class” and “second tier/grade/class” do not limit a priority between the tiers/grades/classes. For another example, the value of the descriptive object is not limited by a prefix and may be one or more. Taking “first apparatus” as an example, the value of the “apparatus” can be one or more. In addition, objects modified by different prefixes may be the same or different. For example, if the descriptive object is an apparatus, “first apparatus” and “second apparatus” may be the same apparatus or different apparatuses, types of the two apparatuses may be the same or different. For another example, if the descriptive object is “information,” “first information” and “second information” may be the same information or different information, contents of “first information” and “second information” may be the same or different.

In some embodiments, “comprise/include A,” “contain A,” “for indicating A,” and “carry A” can be interpreted as directly carrying A, or indirectly indicating A.

In some embodiments, terms such as “. . . ,” “determining . . . ,” “in the case that/of . . . ,” “at the time that/of . . . ,” “when . . . ,” “if . . . ,” “in the event that/of . . . ,” etc., can be exchanged.

In some embodiments, terms such as “greater than,” “greater than or equal to,” “not less than,” “more than,” “more than or equal to,” “no fewer than,” “higher than,” “higher than or equal to,” “not lower than,” “above,” etc., may be used interchangeably. Terms such as “less than,” “less than or equal to,” “not greater than,” “fewer than,” “fewer than or equal to,” “not more than,” “lower than,” “lower than or equal to,” “not higher than,” “below,” etc., can be exchanged.

In some embodiments, the apparatus, etc., can be interpreted as physical or virtual entity, and its name is not limited to that described in the embodiments. Terms such as “apparatus,” “equipment,” “device,” “circuit,” “network element,” “node,” “function,” “unit,” “section,” “system,” “network,” “chip,” “chip system,” “entity,” “subject,” etc., may be exchanged.

Furthermore, each element, each row, or each column in a table of the embodiments of the present disclosure can be implemented as an independent embodiment, and any combination of any element, any row, or any column can also be implemented as an independent embodiment.

In some embodiments, each analog channel corresponds to a sampling system. Each sampling system includes an analog front end, an ADC, a sampling clock, and an FPGA, which independently completes sampling, storage, and necessary data processing of a channel. A respective FPGA of each of the multiple channels aggregates processed data to a common FPGA of the oscilloscope for triggering, display, and other processing. It could be understood that when a unit is configured to synchronously transmit data to another unit according to a synchronization signal, it may mean that the time when the unit starts transmitting data to another unit is synchronized with a rising edge or a falling edge of the synchronization signal. That is, when the rising edge or the falling edge of the synchronization signal arrives, it triggers the unit to transmit data to another unit.

In the oscilloscope of the multi-channel sampling system, synchronization between channels becomes a critical issue that must be addressed. Otherwise, uncertain delay difference exists between the sampled data and the processed data of the oscilloscope, thereby severely affecting the observation and measurement of the oscilloscope to the multi-channel signals.

Therefore, in the oscilloscope of the multi-channel sampling system, ADC sampling and data processing for the channels must be synchronized to reduce the delay difference of sampling for each channel. Data transmitted to the common FPGA requires high alignment. Therefore, reducing the delay difference between channels of the oscilloscope is an urgent issue that needs to be addressed.

FIG. 1 shows an oscilloscope according to an embodiment of the present disclosure. The oscilloscope has N sampling channels and includes:
a first data processing unit 10 configured to send a first synchronization signal to a first multi-output unit 20;
the first multi-output unit 20 configured to output a second synchronization signal to the N sampling channels, respectively, according to the first synchronization signal, where N is an integer greater than or equal to 2; and
an analog-to-digital conversion unit 30 and a second data processing unit 40 corresponding to each of the N sampling channels, where the analog-to-digital conversion unit 30 is configured to perform signal sampling to determine first sampled data, and synchronously transmit the first sampled data to the second data processing unit 40 of a sampling channel to which the analog-to-digital conversion unit belongs, according to the second synchronization signal; and the second data processing unit 40 is configured to process the received first sampled data and send second sampled data obtained by processing the first sampled data to the first data processing unit 10.

Here, the oscilloscope may have multiple sampling channels. Each of the sampling channels may be configured to connect to an external device of the oscilloscope.

In a possible implementation, the external device of the oscilloscope includes an oscilloscope probe.

In a possible implementation, the external device of the oscilloscope may be configured to detect a signal and transmit the detected signal to the oscilloscope through an electrical connection (e.g., an analog input port) between the oscilloscope and the external device.

In a possible implementation, the oscilloscope may further include an analog front end, etc., configured to send the detected signal to the analog-to-digital conversion unit 30. The analog front end may be configured to perform analog signal processing, such as signal amplification on the received signal.

The analog-to-digital conversion unit 30 is configured to perform signal sampling on the signal processed by the analog front end, convert an analog signal into a digital signal (i.e., the first sampled data), and send the first sampled data to the second data processing unit 40. The second data processing unit 40 is configured to perform data processing on the first sampled data and send the second sampled data obtained by processing the first sampled data to the first data processing unit 10 in the oscilloscope. The analog-to-digital conversion unit 30 may include an ADC, etc.

Here, the data processing performed on the first sampled data by the second data processing unit 40 may include at least one of the following:
digital filtering; and
data packet for transmission protocols.

In a possible implementation, the first data processing unit 10 is configured to perform data processing, display, triggering, etc., on the data obtained by each of the sampling channels.

In a possible implementation, an analog-to-digital conversion unit 30 corresponding to each of the N sampling channels may include the analog-to-digital conversion unit 30 included in each of the N sampling channels. Each sampling channel may have one analog-to-digital conversion unit 30.

In a possible implementation, a second data processing unit 40 corresponding to each of the N sampling channels may include the second data processing unit 40 included in each of the N sampling channels. Each sampling channel may have one second data processing unit 40.

In a possible implementation, the first data processing unit 10 may be implemented by an FPGA, but is not limited herein.

In a possible implementation, the second data processing unit 40 may be implemented by an FPGA, which is not limited herein.

In a possible implementation, the first multi-output unit 20 is configured to distribute signals of the oscilloscope to different sampling channels.

In a possible implementation, the first multi-output unit 20 includes at least one of a fanout device, a trigger, and a power divider.

In a possible implementation, the first multi-output unit 20 may be implemented by an FPGA.

In a possible implementation, the first multi-output unit 20 may be implemented using an integrated circuit with clock jitter cancellation capability.

In a possible implementation, different second synchronization signals output by the first multi-output unit 20 based on the same first synchronization signal may have the same signal characteristic for controlling the synchronization of the transmission of the first sampled data by the analog-to-digital conversion units 30, thereby realizing the synchronization of the transmission of the first sampled data by the analog-to-digital conversion units 30. The signal characteristic of the second synchronization signal may include at least one of pulse frequency, pulse edge duration, and a time-domain position of the pulse edge.

In a possible implementation, the second synchronization signal may control the transmission of the first sampled data performed by the analog-to-digital conversion unit 30 via a signal pulse. The second synchronization signal may control the transmission of the first sampled data performed by the analog-to-digital conversion unit 30 via the edge of the signal pulse. Edges of signal pulses of the second synchronization signals from different sampling channels are aligned to achieve the synchronization of the transmission of the first sampled data performed by the analog-to-digital conversion units 30.

In a possible implementation, the second synchronization signal may include one or more signal pulses for controlling the analog-to-digital conversion unit 30 to perform the transmission of the first sampled data.

In a possible implementation, the second synchronization signal may be directly output to the analog-to-digital conversion unit 30 to control the analog-to-digital conversion unit 30 to perform the transmission of the first sampled data.

In a possible implementation, the second synchronization signal may be indirectly output to the analog-to-digital conversion unit 30. For example, it may be further divided into multiple synchronization signals by a subsequent multi-output unit to control the analog-to-digital conversion unit 30 to perform the transmission of the first sampled data. For example, the second synchronization signal may be level-converted by a level conversion circuit, etc., to control the analog-to-digital conversion unit 30 to perform the transmission of the first sampled data.

In a possible implementation, the analog-to-digital conversion unit 30 may send the first sampled data to the second data processing unit 40 via a data bus. The data bus may include an LVDS data bus or a JESD204B data bus.

Thus, the oscilloscope converts the first synchronization signal into second synchronization signals output to different sampling channels through the first multi-output unit 20, the second synchronization signals are configured to synchronize the transmission of the first sampled data performed by the analog-to-digital conversion units 30, thereby realizing synchronization of the transmission of the first sampled data performed by the analog-to-digital conversion units 30 of multiple sampling channels, reducing the delay difference in data transmission between channels of the oscilloscope, and improving the signal detection precision of the oscilloscope.

In some embodiments, the analog-to-digital conversion unit 30 is specifically configured to synchronize, according to the second synchronization signal, start time of transmitting the first sampled data to the second data processing unit 40 of the sampling channel to which the analog-to-digital conversion unit 30 belongs.

In a possible implementation, one second synchronization signal corresponds to an analog-to-digital conversion unit 30 corresponding to one sampling channel. For example, one second synchronization signal is output to an analog-to-digital conversion unit 30 contained in one sampling channel.

In a possible implementation, the second synchronization signal is configured to trigger the analog-to-digital conversion unit 30 to perform the transmission of the first sampled data. That is, the analog-to-digital conversion unit 30 starts transmitting the first sampled data after receiving the second synchronization signal. Since the second synchronization signals of different sampling channels have the same signal characteristic, transmission time of the first sampled data of the analog-to-digital conversion units 30 are the same, thereby realizing the synchronization of the start time of transmitting the first sampled data.

In a possible implementation, the analog-to-digital conversion unit 30 does not have a data buffer. Therefore, triggering the analog-to-digital conversion unit 30 to sample means triggering the analog-to-digital conversion unit 30 to synchronously transmit the first sampled data. That is, “the second synchronization signals are configured to trigger the analog-to-digital conversion units 30 to perform the transmission of the first sampled data” and “the second synchronization signals are configured to trigger the analog-to-digital conversion units 30 to perform sampling” can be exchanged. That is, the second synchronization signals are configured to synchronize the transmission of the first sampled data performed by the analog-to-digital conversion units 30 of multiple sampling channels. It can also be referred to as that the second synchronization signals are configured to synchronize the sampling performed by the analog-to-digital conversion units 30 of multiple sampling channels.

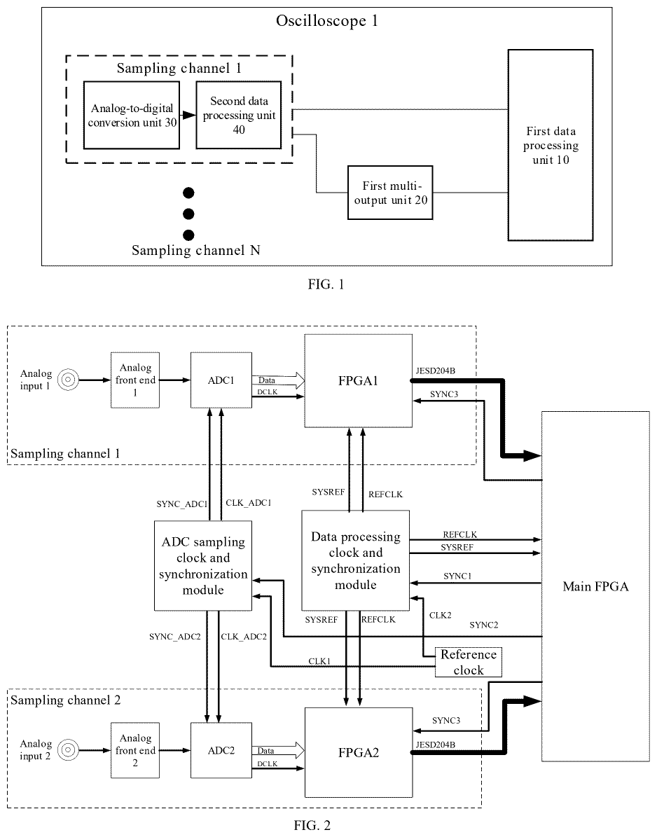

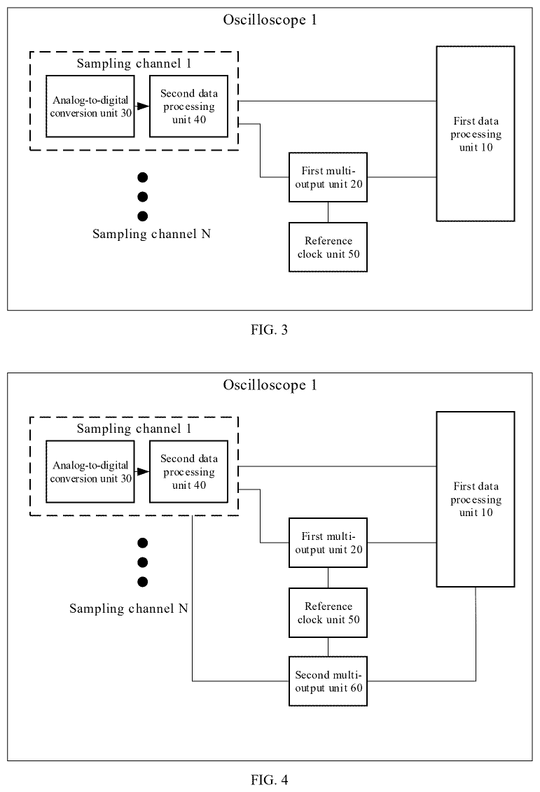

Exemplarily, as shown in FIG. 2, taking N as 2, that is, taking the oscilloscope has two sampling channels as an example to describe this embodiment. The analog-to-digital conversion units 30 of two sampling channels, i.e., ADC1 and ADC2 perform detection and sampling on their respective signals to obtain their respective first sampled data. A main FPGA (i.e., the first data processing unit 10) of the oscilloscope sends SYNC2 (i.e., the first synchronization signal) to an ADC sampling clock and synchronization module (i.e., the first multi-output unit 20). The ADC sampling clock and synchronization module fans out SYNC2 into SYNC_ADC1 and SYNC_ADC2 (i.e., two second synchronization signals). SYNC_ADC1 is output to ADC1 (i.e., the analog-to-digital conversion unit 30), and SYNC_ADC2 is output to ADC2 (i.e., the analog-to-digital conversion unit 30). SYNC_ADC1 and SYNC_ADC2 have the same signal characteristic (such as pulse, etc.). SYNC_ADC1 and SYNC_ADC2 are configured to trigger ADC1 and ADC2 to start transmitting the first sampled data to FPGA1 (the second data processing unit 40) and FPGA2 (the second data processing unit 40), respectively. Since SYNC_ADC1 and SYNC_ADC2 have the same signal characteristic, the start time of transmitting the first sampled data by ADC1 and ADC2 are the same, thereby realizing synchronization of the start time of transmitting the first sampled data.

Thus, the oscilloscope converts the first synchronization signal into the second synchronization signals output to different sampling channels through the first multi-output unit 20, the second synchronization signals are configured to synchronize the start time of the transmission of the first sampled data performed by the analog-to-digital conversion units 30, thereby realizing synchronization of the start time of transmitting the first sampled data for multiple sampling channels, reducing the delay difference in data transmission between channels of the oscilloscope, and improving the signal detection accuracy of the oscilloscope.

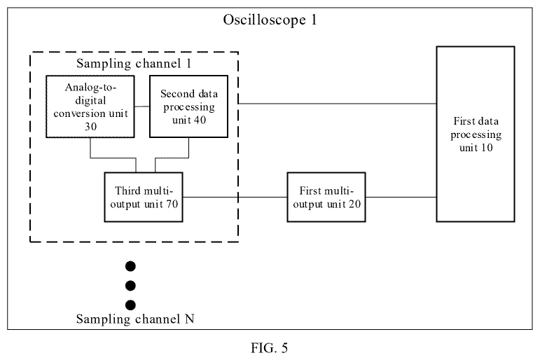

FIG. 3 shows an oscilloscope according to an embodiment of the present disclosure. The oscilloscope further includes:
a reference clock unit 50 configured to send a first reference clock signal to the first multi-output unit 20;
the first multi-output unit 20 is configured to respectively output a first synchronization clock signal to the analog-to-digital conversion units 30 respectively corresponding to the N sampling channels according to the first reference clock signal; and
the analog-to-digital conversion unit 30 is further configured to synchronize a sampling frequency of the signal sampling according to the first synchronization clock signal.

In a possible implementation, the first multi-output unit 20 may output the first reference clock signal as N first synchronization clock signals having the same clock parameter. The first synchronization clock signal may be input into the analog-to-digital conversion unit 30 and configured to determine a sampling clock for the analog-to-digital conversion unit 30.

In a possible implementation, the analog-to-digital conversion unit 30 may use the first synchronization clock signal as the sampling clock. Alternatively, the analog-to-digital conversion unit 30 may perform frequency division on the first synchronization clock signal to obtain the sampling clock.

In a possible implementation, the first multi-output unit 20 may fan out the first reference clock signal into N first synchronization clock signals having the same clock parameter.

In a possible implementation, the clock parameter includes a clock frequency and a clock phase.

The analog-to-digital conversion units 30 of the N sampling channels respectively use the first synchronization clock signals with the same clock parameter to sample, thereby realizing sampling synchronization.

In some embodiments, the first multi-output unit 20 is further configured to synchronize the first synchronization signal with the first reference clock signal. The synchronization between the second synchronization signals fanned out from the first synchronization signal and the first synchronization clock signal is further improved.

In a possible implementation, synchronizing the first synchronization signal with the first reference clock signal may include triggering the first synchronization signal using the first reference clock signal.

In a possible implementation, since the first synchronization signal is synchronized with the first reference clock signal, the first multi-output unit 20 uses the first reference clock signal to fan out the first synchronization clock signal, and the first multi-output unit 20 uses the first synchronization signal to fan out the second synchronization signal. Therefore, the second synchronization signal and the first synchronization clock signal have a first fixed phase difference.

In a possible implementation, the first synchronization clock signal can be used as a clock for a D trigger to trigger the first synchronization signal.

Exemplarily, as shown in FIG. 2, the ADC sampling clock and synchronization module fan out the reference clock CLK1 (i.e., the first reference clock signal) into two signals, CLK_ADC1 and CLK_ADC2 (i.e., two first synchronization clock signals). CLK_ADC1 is output to ADC1 (i.e., the analog-to-digital conversion unit 30), and CLK_ADC2 is output to ADC2 (i.e., the analog-to-digital conversion unit 30). CLK_ADC1 and CLK_ADC2 have the same clock parameter. CLK_ADC1 and CLK_ADC2 are configured for signal sampling by ADC1 and ADC2, respectively. Since CLK_ADC1 and CLK_ADC2 have the same clock parameter, ADC1 and ADC2 can achieve synchronization of the sampling frequencies.

SYNC_ADC1 and SYNC_ADC2 (i.e., the two second synchronization signals) and CLK_ADC (CLK_ADC1 and CLK_ADC2) may have a fixed phase relationship. The D trigger can be configured to synchronize the input synchronization signal SYNC2 with CLK1, and then fanout to obtain SYNC_ADC1 and SYNC_ADC2. The ADC sampling clock CLK_ADC and the synchronization signal SYNC_ADC output to the two sampling channels may have equal delay. If there is a delay error between CLK_ADC and SYNC_ADC, it can be calibrated during channel delay calibration of the oscilloscope.

In some embodiments, the analog-to-digital conversion unit 30 is further configured to output a second synchronization clock signal to the second data processing unit 40 of the sampling channel to which the analog-to-digital conversion unit 30 belongs, according to the first synchronization clock signal. The second data processing unit 40 is further configured to synchronize the processing of the first sampled data according to the second synchronization clock signal.

The analog-to-digital conversion unit 30 may output the second synchronization clock signal according to the first synchronization clock signal. For example, the analog-to-digital conversion unit 30 may fan out the second synchronization clock signal according to the first synchronization clock signal. The analog-to-digital conversion unit 30 may also obtain the second synchronization clock signal by performing frequency division on the first synchronization clock signal, etc.

In a possible implementation, the analog-to-digital conversion units 30 of the sampling channels output the second synchronization clock signals in the same way. Since the first synchronization clock signals of the sampling channels have the same clock parameter, the second synchronization clock signals of the sampling channels of the oscilloscope also have the same clock parameter.

The processing of the first sampled data performed by the second data processing unit 40 includes at least one of the following: performing, by the second data processing unit 40, digital filtering on the first sampled data and performing, by the second data processing unit 40, data packet for transmission protocols on the first sampled data.

Since the second synchronization clock signals of the sampling channels have the same clock parameter, the processing of the first sampled data performed by the second data processing units 40 of the sampling channels are synchronized.

Exemplarily, as shown in FIG. 2, synchronous clocks for internal data processing in FPGA1 and FPGA2 use the synchronous clocks DCLK (i.e., the second synchronization clock signals) for outputting data by ADCs (i.e., the analog-to-digital conversion units 30). Thus, the data processing in FPGA1 and FPGA2 are synchronized with the sampling in ADCs, and the data processing in FPGA1 and FPGA2 are also synchronized.

FIG. 4 shows an oscilloscope according to an embodiment of the present disclosure. The oscilloscope further includes:
a second multi-output unit 60 configured to respectively output a third synchronization signal to the first data processing unit 10 and the second data processing units 40 respectively corresponding to the N sampling channels;
the third synchronization signal is configured to synchronize a frame clock of a data frame corresponding to the second sampled data transmitted between the second data processing unit 40 and the first data processing unit 10.

In a possible implementation, the third synchronization signals corresponding to the N sampling channels have the same signal characteristic. The signal characteristic of the third synchronization signals may include at least one of a time-domain position of a pulse, a time-domain width of the pulse, and an edge duration (rising edge time and/or falling edge time).

In a possible implementation, the second multi-output unit 60 performs multiple outputs of signals.

In a possible implementation, the second multi-output unit 60 includes at least one of a fanout device, a trigger, and a power divider.

In a possible implementation, the second multi-output unit 60 may autonomously output the third synchronization signals, for example, generating pulse signals by performing frequency division on a reference clock, etc.

In a possible implementation, the second data processing unit 40 processes the first sampled data to obtain the second sampled data and sends the second sampled data to the first data processing unit 10 for data processing, etc., through the connection between the second data processing unit 40 and the first data processing unit 10.

In a possible implementation, the second data processing unit 40 may send the second sampled data to the first data processing unit 10 via a data bus. The data bus may include an LVDS data bus, or a JESD204B data bus.

In a possible implementation, the second data processing unit 40 may send the second sampled data to the first data processing unit 10 in the form of data frames. One piece of second sampled data may contain a plurality of data frames, or one data frame may contain a plurality of pieces of second sampled data.

In a possible implementation, data frames are transmitted within the frame clock. One frame clock pulse may include multiple transmission clocks. Here, the transmission clock may be a basic clock signal transmitted between the second data processing unit 40 and the first data processing unit 10. For example, the transmission clock may be a system clock in the JESD204B data bus.

The third synchronization signal may include a frame clock signal pulse. The second multi-output unit 60 may output one or more frame clock signal pulses.

The second data processing unit 40 may send the data frames corresponding to the second sampled data within the time-domain width of the frame clock signal pulse. A plurality of data frames may be sent according to the frame clock signal pulse, thereby realizing the control of the transmission timing of the data frames.

Since the second data processing units 40 of the N sampling channels and the first data processing unit 10 use the same third synchronization signal, the second data processing units 40 of the N sampling channels and the first data processing unit 10 can realize synchronous transmission of the data frames corresponding to the second sampled data.

In some embodiments, the first data processing unit 10 is configured to send a fourth synchronization signal to the second multi-output unit 60; and
the second multi-output unit 60 is specifically configured to output the third synchronization signals according to the fourth synchronization signal.

In a possible implementation, the second multi-output unit 60 may output the third synchronization signals based on the fourth synchronization signal of the first data processing unit 10.

In a possible implementation, the third synchronization signals may be fanned out by the second multi-output unit 60 based on the fourth synchronization signal. The plurality of third synchronization signals may have the same signal parameter.

Exemplarily, as shown in FIG. 2, FPGA1, and FPGA2 are respectively connected to the main FPGA via a JESD204B data bus. The data processing clock and synchronization module (i.e., the second multi-output unit 60) outputs SYSREF (i.e., the third synchronization signal) to FPGA1 and FPGA2, respectively, to synchronize the data frames corresponding to the second sampled data transmitted on the JESD204B data bus. The data processing clock and synchronization module may also fan out the third synchronization signals according to SYNC1 (i.e., the fourth synchronization signal) output by the main FPGA, so that the third synchronization signals of the sampling channels have the same signal characteristic.

In some embodiments, the oscilloscope further includes:
a reference clock unit 50 configured to send a second reference clock signal to the second multi-output unit 60;
the second multi-output unit 60 is configured to respectively output a third synchronization clock signal to the second data processing units 40 respectively corresponding to the N sampling channels and the first data processing unit 10 according to the second reference clock signal; and
the third synchronization clock signal is configured to synchronize a transmission clock of the data frame corresponding to the second sampled data transmitted between the second data processing unit 40 and the first data processing unit 10.

Here, the transmission clock may be a basic clock signal transmitted between the second data processing unit 40 and the first data processing unit 10.

In a possible implementation, the second multi-output unit 60 may output the second reference clock signal as a plurality of third synchronization clock signals having the same clock parameter. The third synchronization clock signals are input into the first data processing unit 10 and the second data processing units 40, respectively, and configured as transmission clocks of data frames corresponding to the second sampled data between the first data processing unit 10 and the second data processing units 40.

In a possible implementation, the second multi-output unit 60 may fan out the second reference clock signal into N+1 third synchronization clock signals having the same clock parameter.

In a possible implementation, the clock parameter includes a clock frequency and a clock phase.

Since the transmission connection (such as data bus) between the first data processing unit 10 and each of the second data processing unit 40 uses the third synchronization clock signal, synchronization of the transmission clocks for transmitting data frames through the transmission connection between the first data processing unit 10 and the second data processing units 40 can be realized.

In a possible implementation, the second multi-output unit 60 may synchronize the fourth synchronization signal with the second reference clock signal and fan out the third synchronization signals.

In a possible implementation, the second multi-output unit 60 may synchronize the fourth synchronization signal with a frequency-divided signal of the second reference clock signal and fan out the third synchronization signals.

In a possible implementation, synchronizing, by the second multi-output unit 60, the fourth synchronization signal with the second reference clock signal may include triggering the fourth synchronization signal using the second reference clock signal.

Triggering, by the second multi-output unit 60, the fourth synchronization signal using the second reference clock signal may cause the third synchronization signal and the third synchronization clock signal to have a second fixed phase difference.

In a possible implementation, the first synchronization clock signal can be used as a D trigger clock to trigger the fourth synchronization signal.

Exemplarily, as shown in FIG. 2, FPGA1 and FPGA2 are respectively connected to the main FPGA via a JESD204B data bus. The data processing clock and synchronization module (i.e., the second multi-output unit 60) respectively outputs REFCLK (i.e., the third synchronization clock signal) to FPGA1, FPGA2, and the main FPGA according to CLK2 (the second reference clock signal) to synchronize data frames corresponding to the second sampled data transmitted on the JESD204B data bus. The data processing clock and synchronization module may also fan out SYSREFs (the third synchronization signals) according to SYNC1 (i.e., the fourth synchronization signal) output by the main FPGA, so that the SYSREFs of the sampling channels have the same signal characteristic.

The data processing clock and synchronization module may also contain a synchronous trigger circuit configured to synchronize SYNC1 output by the main FPGA, generally using the sampling clock CLK2 or its frequency-divided clock for synchronization, and generally using a high-speed D trigger for synchronization. The synchronized SYNC1 is configured to synchronize the output of SYSREFs, thereby ensuring a deterministic phase relationship between SYSREFs and REFCLK.

In some embodiments, the first data processing unit 10 is further configured to respectively output a fifth synchronization signal to the second data processing units 40 respectively corresponding to the N sampling channels; and
the second data processing unit 40 is further configured to synchronize start time of transmitting the second sampled data to the first data processing unit 10 according to the fifth synchronization signal.

In a possible implementation, the first data processing unit 10 may output N fifth synchronization signals to control the start time of transmitting the second sampled data by the second data processing units 40. The N fifth synchronization signals may have the same signal characteristic, thereby realizing the synchronization of the start time of transmitting the second sampled data.

In a possible implementation, the first data processing unit 10 may be implemented by an FPGA, which can output N fifth synchronization signals in a fanout manner, so that the N fifth synchronization signals have the same signal characteristic.

In a possible implementation, the first data processing unit 10 may be implemented by an FPGA, FPGA may control output time, so that the N fifth synchronization signals have the same signal characteristic, which realizes the synchronization of the start time of transmitting the second sampled data, thereby realizing the synchronization of the transmission from the second data processing units 40 to the first data processing unit 10.

By synchronizing the signal sampling of the analog-to-digital conversion units 30 of the sampling channels, synchronizing the transmission of the first sampled data by the analog-to-digital conversion units 30, synchronizing the processing of the first sampled data by the second data processing units 40, and synchronizing the transmission of the second sampled data from the second data processing units 40 to the first data processing unit 10, the synchronization of complete data processing and transmission process of the sampling channels is achieved, thereby reducing the delay difference between channels of the oscilloscope, and improving the accuracy of signal measurement and signal display of the oscilloscope.

Here, this embodiment provides another implementation of an oscilloscope.

As shown in FIGS. 1 and 5, the oscilloscope has N sampling channels and the oscilloscope includes:
a first data processing unit 10 configured to send a first synchronization signal to the first multi-output unit 20;
the first multi-output unit 20 is configured to output a second synchronization signal to the N sampling channels, respectively, according to the first synchronization signal, where N is an integer greater than or equal to 2; and
an analog-to-digital conversion unit 30 and a second data processing unit 40 corresponding to each of the N sampling channels, where the analog-to-digital conversion unit 30 is configured to perform signal sampling to determine first sampled data and transmit the first sampled data to the second data processing unit 40 of the sampling channel, to which the analog-to-digital conversion unit 30 belongs, according to the second synchronization signal; and the second data processing unit 40 is configured to process the received first sampled data and send second sampled data obtained by processing the first sampled data to the first data processing unit 10.

As shown in FIG. 5, the oscilloscope further includes:
a third multi-output unit 70 corresponding to each of the N sampling channels, where the third multi-output unit 70 is configured to receive the second synchronization signal, and output a sixth synchronization signal to the analog-to-digital conversion unit 30 of the sampling channel, to which the third multi-output unit 70 belongs, according to the second synchronization signal; and
the analog-to-digital conversion unit 30 is configured to synchronously transmit a frame clock of a data frame corresponding to the first sampled data to the second data processing unit 40 of the sampling channel, to which the analog-to-digital conversion unit 30 belongs, according to the sixth synchronization signal.

Here, if there is no contradiction, the implementation and working principles of the first data processing unit 10, the first multi-output unit 20, the analog-to-digital conversion unit 30, and the second data processing unit 40 are similar to those in the above-described embodiments and will not be repeated herein.

In a possible implementation, the analog-to-digital conversion unit 30 does not have a data buffer. Therefore, triggering the analog-to-digital conversion unit 30 to perform sampling means triggering the analog-to-digital conversion unit 30 to synchronously transmit the first sampled data. That is, in the case of no contradiction, “the sixth synchronization signals are configured to trigger the analog-to-digital conversion units 30 to perform the transmission of the first sampled data” and “the sixth synchronization signals is configured to trigger the analog-to-digital conversion units 30 to perform sampling” can be exchanged. That is, the sixth synchronization signals are configured to synchronize the analog-to-digital conversion units 30 of the multiple sampling channels to perform the transmission of the first sampled data. It can be also referred to as that the sixth synchronization signals are configured to synchronize the analog-to-digital conversion units 30 of the multiple sampling channels to perform sampling.

In a possible implementation, “a third multi-output unit 70 corresponding to each of the N sampling channels” includes that each of the N sampling channels has a third multi-output unit 70.

In a possible implementation, the third multi-output unit 70 performs multiple outputs of signals.

In a possible implementation, the third multi-output unit 70 includes at least one of a fanout device, a trigger, and a power divider.

In a possible implementation, sixth synchronization signals respectively corresponding to the N sampling channels have the same signal characteristic. The signal characteristic of the sixth synchronization signals may include at least one of a time-domain position of the pulse, a time-domain width of the pulse, and edge duration (rising edge time and/or falling edge time).

In a possible implementation, the analog-to-digital conversion unit 30 performs signal sampling to obtain the first sampled data and sends the first sampled data to the second data processing unit 40 for data processing, etc., through the connection between the analog-to-digital conversion unit 30 and the second data processing unit 40.

In a possible implementation, the analog-to-digital conversion unit 30 may send the first sampled data to the second data processing unit 40 via a data bus. The data bus may include an LVDS data bus or a JESD204B data bus.

In a possible implementation, the analog-to-digital conversion unit 30 may send the first sampled data to the second data processing unit 40 in the form of data frames. One piece of first sampled data may contain a plurality of data frames, or one data frame may contain a plurality of pieces of first sampled data.

In a possible implementation, the data frames are transmitted within the frame clock. One frame clock pulse may include multiple transmission clocks. Here, the transmission clock may be a basic clock signal for transmission between the analog-to-digital conversion unit 30 and the second data processing unit 40.

The sixth synchronization signal may include a frame clock signal pulse. The third multi-output unit 70 may output one or more frame clock signal pulses.

The analog-to-digital conversion unit 30 may send the data frames corresponding to the first sampled data within the time-domain width of the frame clock signal pulse. The plurality of data frames may be sent according to the frame clock signal pulse, thereby realizing the control of the transmission timing of the data frames.

Since the analog-to-digital conversion units 30 of the N sampling channels use the sixth synchronization signals with the same signal characteristic, thus the analog-to-digital conversion units 30 of the N sampling channels can synchronize the transmission of the data frames corresponding to the second sampled data.

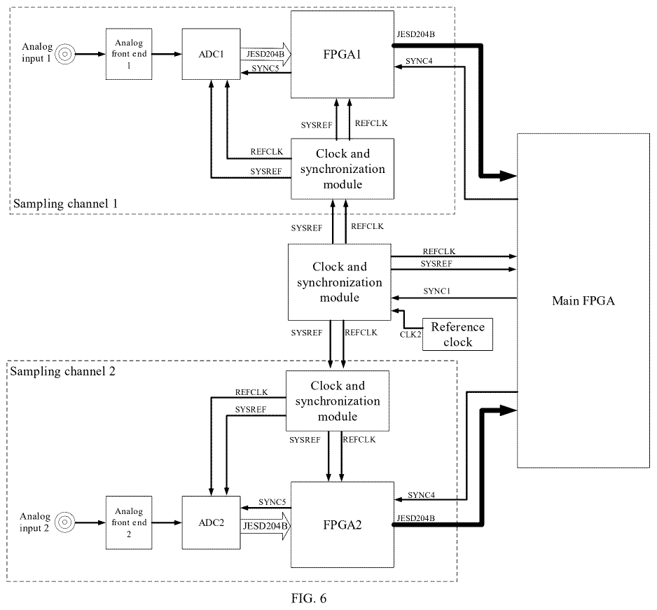

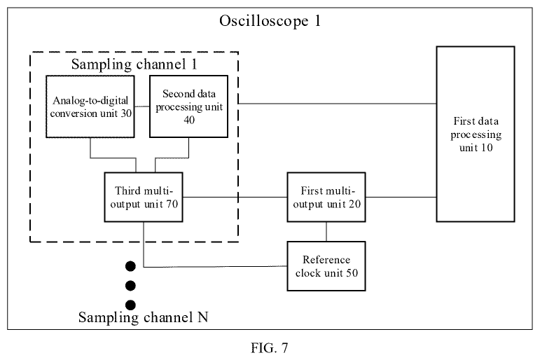

As shown in FIG. 6, the oscilloscope includes a primary clock and synchronization module (i.e., the first multi-output unit 20). Each sampling channel has a secondary clock and synchronization module (i.e., the third multi-output unit 70). The primary clock and synchronization module fans out SYSREF (the second synchronization signal) to each secondary clock and synchronization module based on SYNC1 (the first synchronization signal). The secondary clock and synchronization module output SYSREF to the ADC (the analog-to-digital conversion unit 30) based on the received SYSREF. Within the sampling channel, the ADC (ADC1 or ADC2) and the FPGA (FPGA1 or FPGA2) use a JESD204B data bus. SYSREF is configured to synchronize the frame clocks of the JESD204B data buses between the ADC and the FPGA in the channels.

In some embodiments, as shown in FIG. 7, the oscilloscope further includes:
a reference clock unit 50 configured to send a third reference clock signal to the first multi-output unit 20;
the first multi-output unit 20 is configured to respectively output a fourth synchronization clock signal to the third multi-output units 70 respectively corresponding to the N sampling channels according to the third reference clock signal;
the third multi-output unit 70 is further configured to output a fifth synchronization clock signal to the analog-to-digital conversion unit 30 of the sampling channel to which the third multi-output unit 70 belongs, according to the fourth synchronization clock signal; and
the analog-to-digital conversion unit 30 is configured to synchronously transmit the transmission clock of the data frame corresponding to the first sampled data to the second data processing unit 40 of the sampling channel to which the analog-to-digital conversion unit 30 belongs.

Here, the transmission clock may be the basic clock signal for transmission between the analog-to-digital conversion unit 30 and the second data processing unit 40.

The first multi-output unit 20 receives the third reference clock signal of the reference clock unit 50 and fans out the fourth synchronization clock signals to the third multi-output units 70 of the sampling channels. The multiple fourth synchronization clock signals may have the same clock parameter.

The third multi-output unit 70 can output the fifth synchronization clock signal according to the fourth synchronization clock signal. The fifth synchronization clock signal can be input into the analog-to-digital conversion unit 30 and configured to transmit the transmission clock of the data frame corresponding to the first sampled data for the analog-to-digital conversion unit 30. The multiple fifth synchronization clock signals may have the same clock parameter.

In a possible implementation, the clock parameter includes a clock frequency and a clock phase.

Since each of the analog-to-digital conversion units 30 uses the fifth synchronization clock signal for transmission, the synchronization of the transmission clocks of the data frames corresponding to the first sampled data transmitted by the analog-to-digital conversion units 30 can be achieved.

As shown in FIG. 6, the oscilloscope includes a primary clock and synchronization module (i.e., the first multi-output unit 20). Each sampling channel has a secondary clock and synchronization module (i.e., the third multi-output unit 70). The primary clock and synchronization module fans out REFCLK (the fourth synchronization clock signal) to each secondary clock and synchronization module based on CLK3 (the third reference clock signal). The secondary clock and synchronization module outputs REFCLK to the ADC (the analog-to-digital conversion unit 30) based on the received REFCLK. Within the sampling channel, the ADC (ADC1 or ADC2) and the FPGA (FPGA1 or FPGA2) use the JESD204B data bus. REFCLK is configured to synchronize transmission clocks of the JESD204B data buses between ADCs and FPGAs in the channels.

In some embodiments, the first multi-output unit 20 is further configured to output a seventh synchronization signal to the first data processing unit 10 according to the first synchronization signal;
the third multi-output unit 70 is further configured to output an eighth synchronization signal to the second data processing unit 40 of the sampling channel to which the third multi-output unit 70 belongs, according to the second synchronization signal; and
the seventh synchronization signal and the eighth synchronization signal are configured to synchronize the frame clock of the data frame corresponding to the second sampled data transmitted between the second data processing unit 40 and the first data processing unit 10.

Both the seventh synchronization signal and the eighth synchronization signal are both fanned out step by step based on the first synchronization signal. Therefore, the seventh synchronization signal and the eighth synchronization signal may have the same signal characteristic. The seventh synchronization signal may be input into the first data processing unit 10, and the eighth synchronization signal may be input into each of the second data processing units 40 to synchronize the frame clock of the data frame corresponding to the second sampled data transmitted between the first data processing unit 10 and each of the second data processing units 40.

The first data processing unit 10 and the second data processing unit 40 can be connected via a JESD204B data bus to transmit the data frame corresponding to the second sampled data.

A manner of transmitting the data frame between the first data processing unit 10 and the second data processing unit 40 is similar to a manner of transmitting the data frame between the analog-to-digital conversion unit 30 and the second data processing unit 40, which is not repeated herein.

In a possible implementation, the sixth synchronization signal is fanned out by the third multi-output unit 70 based on the second synchronization signal. Therefore, the sixth synchronization signals of the channels can have the same signal characteristic, thereby realizing the synchronization of the transmission of the first sampled data.

In a possible implementation, the sixth synchronization signal, the seventh synchronization signal, and the eighth synchronization signal are all fanned out step by step based on the first synchronization signal. Therefore, the sixth synchronization signal, the seventh synchronization signal, and the eighth synchronization signal can have the same signal characteristic, thereby realizing the synchronization of the data transmission of the sampling channels.

As shown in FIG. 6, the oscilloscope includes a primary clock and synchronization module (i.e., the first multi-output unit 20). Each sampling channel has a secondary clock and synchronization module (i.e., the third multi-output unit 70). The primary clock and synchronization module fans out SYSREF (the seventh synchronization clock signal) and SYSREF (the second synchronization clock signal) to the main FPGA and each of the secondary clock and synchronization modules based on SYNC1 (the first reference clock signal), respectively. The secondary clock and synchronization module outputs SYSREF (the eighth synchronization signal) to the FPGA (FPGA1 or FPGA2) (the second data processing unit 40) of each sampling channel based on the received SYSREF. The main FPGA and the FPGA (FPGA1 or FPGA2) within each sampling channel use a JESD204B data bus. SYSREFs are configured to synchronize the frame clocks of the JESD204B data buses between the FPGAs (FPGA1 or FPGA2) in the channels and the main FPGA.

In some embodiments, the oscilloscope further includes:
the third multi-output unit 70 further configured to output a sixth synchronization clock signal to the second data processing unit 40 according to the fourth synchronization clock signal; and
the first multi-output unit 20 configured to output a seventh synchronization clock signal to the first data processing unit 10 according to the third reference clock signal;
where the sixth synchronization clock signal and the seventh synchronization clock signal are configured to synchronize the transmission clock of the data frame corresponding to the second sampled data transmitted between the second data processing unit 40 and the first data processing unit 10.

Here, the transmission clock may be a basic clock signal for the transmission between the second data processing unit 40 and the first data processing unit 10.

Both the sixth synchronization clock signals and the seventh synchronization clock signal are fanned out based on the third reference clock signal, therefore, they may have the same signal characteristic. The seventh synchronization clock signal may be input into the first data processing unit 10, and the sixth synchronization clock signal may be input into each of the second data processing units 40 to synchronize the transmission clock of the data frame corresponding to the second sampled data transmitted between the first data processing unit 10 and each of second data processing units 40.

The first data processing unit 10 and the second data processing unit 40 can be connected via a JESD204B data bus for transmitting the data frame corresponding to the second sampled data.

A manner of transmitting the data frame between the first data processing unit 10 and the second data processing unit 40 is similar to a manner of transmitting the data frame between the analog-to-digital conversion unit 30 and the second data processing unit 40, which is not repeated herein.

In a possible implementation, the fifth synchronization clock signal and the sixth synchronization clock signal are fanned out by the third multi-output unit 70 based on the fourth synchronization clock signal, therefore, they can have the same clock parameter, thereby realizing the synchronization of the transmission of the first sampled data.

In a possible implementation, the fifth synchronization clock signal, the sixth synchronization clock signal, and the seventh synchronization clock signal are all fanned out step by step based on the third reference clock signal. Therefore, the fifth synchronization clock signal, the sixth synchronization clock signal, and the seventh synchronization clock signal may have the same clock parameter, thereby realizing the synchronization of the data transmission of the sampling channels.

As shown in FIG. 6, the oscilloscope includes a primary clock and synchronization module (i.e., the first multi-output unit 20). Each sampling channel has a secondary clock and synchronization module (i.e., the third multi-output unit 70). The primary clock and synchronization module fans out REFCLK (the seventh synchronization clock signal) and REFCLK (the fourth synchronization clock signal) to the main FPGA (first data processing unit 10) and each of the secondary clock and synchronization modules, respectively, based on CLK3 (the third reference clock signal). The secondary clock and synchronization module outputs REFCLK (the sixth synchronization clock signal) to the FPGA (FPGA1 or FPGA2) (the second data processing unit 40) of each sampling channel based on the received REFCLK. The main FPGA and the FPGA (FPGA1 or FPGA2) within each sampling channel use a JESD204B data bus. REFCLK is configured to synchronize the transmission clock of the JESD204B data bus between the FPGA (FPGA1 or FPGA2) in each channel and the main FPGA.

In some embodiments, the first data processing unit 10 is further configured to output a ninth synchronization signal to the second data processing units 40 respectively corresponding to the N sampling channels, respectively; and
the second data processing unit 40 is further configured to synchronously transmit start time of transmitting the second sampled data to the first data processing unit 10 according to the ninth synchronization signal.

In a possible implementation, the first data processing unit 10 may output N ninth synchronization signals for controlling the start time of transmitting the second sampled data by the second data processing units 40. The N ninth synchronization signals may have the same signal characteristic, thereby synchronizing start time of transmitting the second sampling data.

In a possible implementation, the first data processing unit 10 may be implemented by an FPGA. FPGA may output N ninth synchronization signals in a fanout manner, so that the N ninth synchronization signals have the same signal characteristic.

In a possible implementation, the first data processing unit 10 may be implemented by an FPGA. FPGA may cause the N ninth synchronization signals have the same signal characteristic by controlling the output time, thereby realizing the synchronization of the start time of transmitting the second sampled data.

As shown in FIG. 6, the main FPGA (the first data processing unit 10) outputs SYNC4 (the ninth synchronization signal) to the FPGA (FPGA1 or FPGA2) (the second data processing unit 40) of each sampling channel to achieve the synchronization of the start time of transmitting the second sampling data.

In some embodiments, the second data processing unit 40 is further configured to output a tenth synchronization signal to the analog-to-digital conversion unit 30 of the sampling channel to which the second data processing unit 40 belongs, according to the ninth synchronization signal.

The analog-to-digital conversion unit 30 is further configured to synchronize the start time of transmitting the first sampled data to the second data processing unit 40 according to the tenth synchronization signal.

In a possible implementation, the tenth synchronization signal may be triggered based on the ninth synchronization signal. Since the ninth synchronization signals have the same signal characteristic, the tenth synchronization signals can also have the same signal characteristic. The N tenth synchronization signals can have the same signal characteristic, thereby realizing the synchronization of the start time of transmitting the first sampled data.

As shown in FIG. 6, the FPGA (FPGA1 or FPGA2) (the second data processing unit 40) of each sampling channel outputs SYNC5 (the tenth synchronization signal) to a corresponding ADC (ADC1 or ADC2) to realize the synchronization of the start time of transmitting the first sampled data.

By synchronizing the sampling and transmission of the first sampled data of the analog-to-digital conversion units 30 of the sampling channels, synchronizing the processing of the first sampled data by the second data processing units 40, and synchronizing the transmission of the second sampled data from the second data processing units 40 to the first data processing unit 10, the synchronization of complete data processing and transmission process of the sampling channels is achieved, thereby reducing the delay difference between channels of the oscilloscope and improving the accuracy of signal measurement and signal display of the oscilloscope.

It should be understood that the above embodiments are illustrative and are not intended to include all possible embodiments included in the claims. Various modifications and changes can be made to the above embodiments without departing from the scope of the embodiments of the present disclosure. Similarly, various technical features of the above embodiments can be arbitrarily combined to form other embodiments of the present disclosure that may not be explicitly described. Therefore, the above embodiments only express several implementations of the present disclosure and do not limit the protection scope of the present disclosure.

In conjunction with any of the above embodiments, a plurality of specific examples are provided below:

In an oscilloscope with a high-bandwidth and a high-sample-rate, due to a high ADC sampling rate and large data throughput, each ADC has an independent sampling channel. The sampling channel includes an analog input, an analog front end, ADC, and FPGA. Outputs of multiple sampling channels are aggregated into the main FPGA for alignment, triggering, data processing, and display of multi-channel sampling data.

After storing and processing the ADC sampling data, multiple sampling channels aggregate the data to another FPGA (generally on a mainboard) for display, analysis, and other processing.

Multiple sampling channels correspond to multiple independent channels of the oscilloscope. The channels of the oscilloscope need to ensure relatively small channel delay and sampling synchronization. After the ADC sampling data are synchronized, data transmission from the multiple independent sampling units to the mainboard also need to be synchronized to ensure the synchronization of the data finally aggregated to the FPGA in the mainboard from multiple channels.

As shown in FIG. 2, for ADC sampling synchronization in this embodiment, the oscilloscope has an ADC sampling clock and synchronization module which has two input signals: one is the reference clock CLK1 from the oscilloscope, and the other is the synchronization signal SYNC2 from the main FPGA. The ADC sampling clock and synchronization module outputs two ADC sampling clocks. These two ADC sampling clocks have the same frequency and phase. These two synchronized sampling clocks are provided to the ADCs of the sampling channels as the sampling clocks of the ADCs, respectively. The ADC sampling clock and synchronization module simultaneously outputs two ADC synchronization signals. These two synchronization signals are generally pulse signals and have a fixed phase relationship with the sampling clock CLK_ADC. Generally, a D trigger can be configured to synchronize the input synchronization signals SYNC2 using CLK_ADC, and then fan out an output. The ADC sampling clocks and the synchronization signals output to the two sampling channels must be normal and ensure equal delay for the sampling clocks and the SYNCs reaching ADC1 and ADC2. If there is an error, they can be calibrated during the delay calibration on channels of the oscilloscope.

By ensuring equal delay or a deterministic phase of the ADC sampling clock and the synchronization signal, sampling of two ADCs are synchronous, the SYNCs are synchronous, and the output data from the ADCs are also ensured to be synchronous. The ADC can be of LVDS type or JESD204B type.

The synchronization of the sampling clock and the synchronization signal do not affect other calibration items of the two ADCs. After the ADCs are calibrated, the main FPGA should send the synchronization signal SYNC2 again to synchronize the output data from the ADCs, and the output data are ensured to be synchronized.

The second aspect of this embodiment is to ensure that the data processing in FPGA1 and FPGA2 and the output transmission from the FPGA1 and FPGA2 to the main FPGA are also synchronized. The synchronous clock for internal data processing in FPGA1 and FPGA2 uses the synchronous clock DCLK of the output data from the ADCs. In this way, the data processing in FPGA1 and FPGA2 are synchronized with the ADC sampling, so that the data processing in FPGA1 and FPGA2 are also synchronized.

The oscilloscope also includes a data processing clock and synchronization module, configured to generate the reference clock REFCLK and the system synchronization reference signal SYSREF for data transmission between FPGAs. The embodiment addresses the synchronization of data transmission from multiple FPGAs to the main FPGA. High-speed serial buses are used between FPGAs, and JESD204B or JESD204C protocol is used. FPGA with a high-speed serial bus is selected and the JESD204B protocol is supported. A JESD204B serial communication interface is adopted between the FPGA of the sampling channel and the main FPGA. JESD204B DATA serial data is transmitted to the main FPGA from FPGA. Since there are deterministic latency between devices using JESD204B, the synchronization of data transmitted from multiple FPGAs to the main FPGA can be ensured.

In the JESD204B data bus, data can be divided into frames and continuously sent to a receiver. By using the System Reference Event signal (SYSREF), data in multiple serial channel links are aligned to SYSREF to synchronize internal frame clocks of the transmitter and the receiver, so that the devices using the JESD204B link have deterministic latency. The frame clock alignment, data code synchronization, and frame and link synchronization are completed in sequence by generally relying on the system synchronization reference signal SYSREF and the synchronization signal SYNC. Synchronized data transmission and reception of the JESD204B has deterministic delay.

This embodiment focuses on how the clocks and the SYSREF of the main FPGA and each of the sampling channels are generated and distributed to realize synchronization of data transmission between the sampling channels and the main FPGA.

The data processing clock and synchronization module uses another output (CLK2) of the reference clock as its input clock. Two outputs of the reference clock must have the same frequency and a deterministic phase, and two signals are output in a power-divided manner. Another input of the data processing clock and synchronization module is SYNC1, which is from the main FPGA and is configured to synchronize SYSREFs. The data processing clock and synchronization module outputs three reference clocks and SYSREFs, which are connected to FPGA1, FPGA2, and the main FPGA, respectively. As the reference clock for the JESD204B communication module, SYSREF is configured to synchronize internal frame clocks of a transceiver, so that data transmission delay between FPGA1 and the main FPGA and between FPGA2 and the main FPGA are the same. Interfaces between FPGA1 and the main FPGA and between FPGA2 and the main FPGA are data transmission interfaces of the JESD204B. There is a synchronization signal SYNC3 from the main FPGA to FPGA1 and from the main FPGA to FPGA2, respectively, which is configured to synchronize the start of the output transmission of FPGA1 and FPGA2, thus ensuring the synchronization of the output transmission between FPGAs.

A synchronization process of the multi-sampling channels of the entire oscilloscope is as follows:
1. Synchronization of sampling clocks of ADCs and synchronization of sampling SYNC;
2. Data processing within the FPGA and synchronization of ADC data clocks;
3. Synchronization of link establishment between FPGAs;
4. The main FPGA synchronizes the output transmission of FPGA1/2 via SYNC.

Thus, the entire oscilloscope system, from sampling to output, is strictly synchronized, thereby ensuring that the sampling data transmitted to the main FPGA are analog signals sampled at the same time and realizing synchronization of multiple sampling channels.

The solution of the multi-channel sampling synchronization of the oscilloscope provided in this embodiment can be applied to the oscilloscope with a high-bandwidth and a high-sample-rate, and can be applied in a scenario where each channel has independent sampling processing, achieving an effect of strict sampling channel synchronization. Moreover, the provided sampling synchronization method is widely applicable, which is not limited by the type of ADC, is simpler to use, and can be applied to most of mid-to-high-end oscilloscopes. Therefore, this embodiment has very wide application prospect.

### Example 1

In this embodiment, for the ADC sampling clock and synchronization module, the sampling clock CLK_AD1/CLK_AD2 is generally implemented by a phase-locked loop and a power divider to ensure that the output frequency and the phase noise meet the requirements of ADC. The reference clock serves as the input reference for the phase-locked loop.

In this embodiment, the SYNC signal is generally fanned out after the SYNC2 output by the main FPGA is synchronized. The synchronization is generally performed by a sampling clock or its frequency-divided clock, and generally performed by a high-speed D trigger, to ensure a deterministic phase relationship between SYNC and the sampling clock.

In this embodiment, a clock distribution circuit that meets JESD204B is generally selected as the data processing clock and synchronization module, which generally includes a phase-locked loop and a fanout circuit for generating multiple reference clocks REFCLK from the same source and a synchronization reference signal SYSREF, which is generally a pulse or a continuous pulse clock, and SYSREF and REFCLK are synchronous. The data processing clock and synchronization module also includes a synchronous trigger circuit, which is configured to synchronize SYNC2 output by the main FPGA. The synchronization is generally performed by a sampling clock or its frequency-divided clock, and generally performed by a high-speed D trigger. to ensure a deterministic phase relationship between SYNC and the sampling clock. The synchronized SYNC2 is configured to synchronize the output of SYSREF to ensure a deterministic phase relationship between SYNC and the sampling clock.

In this embodiment, the data processing clock and synchronization module may be composed of a combination of a plurality of devices, such as a clock generation chip and a clock distribution circuit. The data processing clock and synchronization module may also use a clock generator that includes the above functions, such as LMK04826 or LMK04828 from Texas Instruments or LTC6952 from Analog Devices, Inc.

In this embodiment, ADC may be an ADC with an LVDS parallel output interface.

In this embodiment, FPGA is selected from FPGAs supporting the JESD204B serial interface.

In this embodiment, the analog front end, ADC, and FPGA1/FPGA2 in this embodiment need to be controlled. The control of the analog front end and ADC can be performed by FPGA of the sampling channel or by the main FPGA.

In this embodiment, the clock and the synchronization signal output by the clock and synchronization module and PCB design need to be controlled with an equal length to meet the setup and hold time requirements of the entire circuit board, connectors, backplanes, and various elements.

In this embodiment, the ADC sampling clock and synchronization module, the data processing clock and synchronization module also need to be controlled and are controlled by the main FPGA (not shown in FIG. 2), through an SPI or I2C interface.

### Example 2

As shown in FIG. 6, Example 2 provides a synchronization solution using a high-speed ADC with a JESD204B interface.

As more high-speed ADCs using JESD204B or JESD204C chip, the demand for the I/O number of FPGA can be significantly reduced.

Since ADC itself only is a reference clock REFCLK and synchronization reference signal SYSREF of JESD204B, the synchronization becomes simple.

Each sampling channel contains a secondary clock and synchronization module. The secondary clock and synchronization module outputs multiple reference clocks and synchronization reference signals to synchronize the ADC and FPGA within each sampling channel.

A plurality of FPGAs may also be cascaded, and the synchronization can be ensured as long as JESD204B interface is used between the FPGAs.

REFCLK and SYSREF output by a primary clock and synchronization module serve as inputs of the secondary clock and synchronization module. In the secondary clock and synchronization module, REFCLK is only buffered and fanned out and does not pass through a phase-locked loop, otherwise the synchronization relationship between REFCLKs in the two primary and secondary clock and synchronization modules would be disrupted, and an uncertain phase is generated. SYSREF in the secondary clock and synchronization module may also be directly fanned out to ensure the synchronization relationship. If the secondary SYSREF passes through the D trigger and REFCLK is used as the clock of the D trigger, the synchronization relationship between SYSREF and REFCLK would not be disrupted and can be used.

In this embodiment, the secondary clock and synchronization module may be constituted by a high-speed fanout device, a trigger, etc.
1. The synchronization of the oscilloscope with multi-sampling channels provided in this embodiment can solve the problem of being unable to use a single FPGA to receive and process all ADC data under a high sampling rate, and a two-tier FPGA sampling synchronization structure is provided.
2. This embodiment can simultaneously ensure the synchronization of high sampling rate and data transmission of ADC and ensure strict synchronization of independent channel sampling modules.
3. The synchronization generation method provided in this embodiment has wide applicability and can be used in different types of ADCs, which can be used simply.

Those skilled in the art, after considering the description and practicing the disclosure disclosed herein, will readily conceive other implementation solutions of the present disclosure. The embodiments of the present disclosure are intended to cover any variations, uses, or adaptive changes of the present disclosure that follow the general principle of the present disclosure and include common knowledge or conventional technical means in the technical field not disclosed in the embodiments of the present disclosure. The description and embodiments are to be regarded exemplary only, the true scope and spirit of the present disclosure are indicated by the following claims.

It should be understood that the present disclosure is not limited to the precise structures described above and shown in the drawings, and various modifications and changes can be made without departing from its scope. The scope of the present disclosure is limited only by the appended claims.

1. An oscilloscope, wherein the oscilloscope has N sampling channels and the oscilloscope comprises:
a first data processing unit configured to send a first synchronization signal to a first multi-output unit;
the first multi-output unit configured to output a second synchronization signal to the N sampling channels, respectively, according to the first synchronization signal, wherein N is an integer greater than or equal to 2;
an analog-to-digital conversion unit and a second data processing unit corresponding to each of the N sampling channels, wherein the analog-to-digital conversion unit is configured to perform signal sampling to determine first sampled data, and synchronously transmit the first sampled data to the second data processing unit of a sampling channel to which the analog-to-digital conversion unit belongs, according to the second synchronization signal; and the second data processing unit is configured to process the received first sampled data and send second sampled data obtained by processing the first sampled data to the first data processing unit; and
a second multi-output unit configured to output a third synchronization signal to second data processing units respectively corresponding to the N sampling channels and the first data processing unit, respectively,
wherein the third synchronization signal is configured to synchronize a frame clock of a data frame corresponding to the second sampled data transmitted between the second data processing unit and the first data processing unit.

2. The oscilloscope according to claim 1, wherein
the analog-to-digital conversion unit is specifically configured to synchronize start time of transmitting the first sampled data to the second data processing unit of the sampling channel to which the analog-to-digital conversion unit belongs, according to the second synchronization signal.

3. The oscilloscope according to claim 2, wherein the oscilloscope further comprises:
a reference clock unit configured to send a first reference clock signal to the first multi-output unit,
wherein the first multi-output unit is configured to respectively output a first synchronization clock signal to analog-to-digital conversion units respectively corresponding to the N sampling channels according to the first reference clock signal ; and
the analog-to-digital conversion unit is further configured to synchronize a sampling frequency of the signal sampling according to the first synchronization clock signal.

4. The oscilloscope according to claim 3, wherein
the first multi-output unit is further configured to synchronize the first synchronization signal with the first reference clock signal.

5. The oscilloscope according to claim 3, wherein
the analog-to-digital conversion unit is further configured to output a second synchronization clock signal to the second data processing unit of the sampling channel to which the analog-to-digital conversion unit belongs, according to the first synchronization clock signal; and
the second data processing unit is further configured to synchronize processing of the first sampled data according to the second synchronization clock signal.

6. (canceled)

7. The oscilloscope according to claim 1, wherein
the first data processing unit is configured to send a fourth synchronization signal to the second multi-output unit; and
the second multi-output unit is specifically configured to output the third synchronization signal according to the fourth synchronization signal.

8. The oscilloscope according to claim 1, wherein the oscilloscope further comprises:
a reference clock unit configured to send a second reference clock signal to the second multi-output unit,
wherein the second multi-output unit is configured to output a third synchronization clock signal to the second data processing units respectively corresponding to the N sampling channels and the first data processing unit, respectively, according to the second reference clock signal ; and
wherein the third synchronization clock signal is configured to synchronize a transmission clock of the data frame corresponding to the second sampled data transmitted between the second data processing unit and the first data processing unit.

9. The oscilloscope according to claim 1, wherein
the first data processing unit is further configured to output a fifth synchronization signal to the second data processing units respectively corresponding to the N sampling channels, respectively; and
the second data processing unit is further configured to synchronize start time of transmitting the second sampled data to the first data processing unit according to the fifth synchronization signal.
